(19) United States
(12) Patent Application Publication
(10) Pub. No.: US 2026/0282625 A1
(43) Pub. Date: Sep. 17, 2026

(54) METHOD FOR PRODUCING AN OPTOELECTRONIC COMPONENT, AND OPTOELECTRONIC COMPONENT

(71) Applicant: ams-OSRAM International GmbH, Regensburg (DE)

(72) Inventors: Zeljko PAJKIC, Regensburg (DE); Johann RAMCHEN, Hausen (DE); Ulrich STREPPEL, Regensburg (DE)

(21) Appl. No.: 19/472,047

(22) PCT Filed: May 2, 2024
(86) PCT No.: PCT/EP2024/062133

§ 371 Date: Oct. 2, 2025

(30) Foreign Application Priority Data
May 2, 2023 (DE) 10 2023 111 267.8

(51) Int. Cl. H10H 29/01; H01S 5/02325; H01S 5/0233; H01S 5/42; H10F 39/95; H10H 29/24

(52) U.S. Cl. CPC H10H 29/011; H01S 5/02325; H01S 5/0233; H01S 5/423; H10F 39/95; H10H 29/0361; H10H 29/24

(57) ABSTRACT

The invention relates to a method for producing an optoelectronic component comprising steps for forming a grid having connecting pieces of an electrically conductive material on a rear side of a transparent substrate, wherein cells of the grid are formed between the connecting pieces, for arranging a wavelength-converting material in at least one cell of the grid, for arranging optoelectronic semiconductor chips over the cells of the grid, wherein each optoelectronic semiconductor chip has a front side and a rear side, wherein the front sides of the optoelectronic semiconductor chips are orientated towards the rear side of the substrate, wherein the optoelectronic semiconductor chips are electrically conductively connected to the grid, for arranging a filler material on the rear side of the substrate.

The present invention relates to a method for producing an optoelectronic component and to an optoelectronic component.

This patent application claims the priority of the German patent application 10 2023 111 267.8, the disclosure content of which is incorporated here by reference.

Pixelated optoelectronic components are known in the prior art and are used, for example, as headlamps in motor vehicles. In such components, a high contrast ratio between neighboring pixels is desirable.

It is an object of the present invention to specify a method for producing an optoelectronic component. It is a further object of the present invention to provide an optoelectronic component. These objects are achieved by a method for producing an optoelectronic component and by an optoelectronic component which have the features of the independent claims. Various developments are specified in the dependent claims.

A method for producing an optoelectronic component comprises steps of forming a grid having walls consisting of an electrically conductive material on a back side of a transparent substrate, cells of the grid being formed between the walls, of arranging a wavelength-converting material in at least one cell of the grid, of arranging optoelectronic semiconductor chips over the cells of the grid, each optoelectronic semiconductor chip comprising a front side and a back side, the front sides of the optoelectronic semiconductor chips being oriented toward the back side of the substrate, the optoelectronic semiconductor chips being electrically conductively connected to the grid, of arranging a filler material on the back side of the substrate, the optoelectronic semiconductor chips being embedded in the filler material in such a way that the back sides of the optoelectronic semiconductor chips are not covered by the filler material, and of arranging a driver chip over the back sides of the optoelectronic semiconductor chips, the optoelectronic semiconductor chips being electrically conductively connected to the driver chip.

In this method, the optoelectronic component is constructed upside down on the substrate, which is as an active outer side. The grid for the electrical contacting of the optoelectronic semiconductor chips, which is provided on the back side of the substrate, may advantageously also ensure optical separation of the pixels, embodied by the optoelectronic semiconductor chips, of the optoelectronic component obtainable by the method, which can ensure an increased contrast ratio. The grid is additionally used to receive the wavelength-converting material, so that the optoelectronic component obtainable by the method can offer integrated wavelength conversion. A further advantage of the method and of the optoelectronic component obtainable by the method is that the optoelectronic semiconductor chips are electrically contacted both from their front sides and from their back sides, which can simplify the conductor layout and improve thermal coupling of the optoelectronic semiconductor chips. The method may be carried out at the wafer level, which can advantageously lead to favorable production costs.

In one embodiment of the method, a further step of providing a via structure, which is electrically conductively connected to the grid, on the back side of the substrate is carried out before the arranging of the filler material. The via structure is embedded in the filler material in such a way that a back side of the via structure is not covered by the filler material. Following this, the via structure is electrically conductively connected to the driver chip. In this way, the via structure establishes an electrically conductive connection between the driver chip and the grid arranged on the back side of the substrate, and therefore an electrically conductive connection between the driver chip and the electrical contacts of the optoelectronic semiconductor chips that are arranged on the front sides of the optoelectronic semiconductor chips.

In one embodiment of the method, no wavelength-converting material is arranged in at least one cell of the grid. In this way, the method offers the advantage that the different cells and therefore the different pixels of the optoelectronic component obtainable by the method may be configured differently.

In one embodiment of the method, the filler material is also arranged in cells in which no wavelength-converting material is arranged. Advantageously, a cavity between the front side of an optoelectronic semiconductor chip and the back side of the substrate is avoided in this way, so that detrimental discontinuities of a refractive index in this region can be avoided.

In one embodiment of the method, optoelectronic semiconductor chips of different types are arranged over the cells of the grid. Advantageously, this makes it possible to form pixels of the optoelectronic component obtainable by the method which have different properties.

In one embodiment of the method, a further step of removing a part of the filler material, in order to expose the back sides of the optoelectronic semiconductor chips, is carried out after the arranging of the filler material on the back side of the substrate. This makes it possible to arrange the filler material initially so that the back sides of the optoelectronic semiconductor chips are covered by the filler material. Subsequently, the back sides of the optoelectronic semiconductor chips are exposed again by the removal of a part of the filler material. Advantageously, the method may in this way be carried out particularly simply.

In one embodiment of the method, a further step of arranging an electrically conductive connecting material on the walls of the grid is carried out before the arranging of the optoelectronic semiconductor chips. The optoelectronic semiconductor chips are then electrically conductively connected to the grid via the connecting material.

Advantageously, this allows particularly simple establishment of electrically conductive connections between the optoelectronic semiconductor chips and the grid.

In one embodiment of the method, the grid is formed with a thickness of between 2 μm and 20 μm. Advantageously, the cells of the grid are in this way suitable for receiving wavelength-converting material. Furthermore, the grid in this way allows optical separation of the individual pixels of the optoelectronic component obtainable by the method.

In one embodiment of the method, in addition to the grid, further identical grids are formed on the back side of the substrate. The processing steps above are also carried out for each further grid. The driver chip is provided together with identical further driver chips in a wafer assembly. The optoelectronic semiconductor chips allocated to one of the further grids are electrically conductively connected to one of the further driver chips. To complete the processing, the optoelectronic component and further identical optoelectronic components are singulated. Advantageously, the method in this way allows parallel production of a multiplicity of identical optoelectronic components at the wafer level. This makes it possible to carry out the method particularly economically.

An optoelectronic component comprises a transparent substrate having a back side. A grid having walls consisting of an electrically conductive material is formed on the back side of the substrate. Cells of the grid are formed between the walls. A wavelength-converting material is arranged in at least one cell of the grid. Optoelectronic semiconductor chips are arranged over the cells of the grid, each optoelectronic semiconductor chip comprising a front side and a back side. The front sides of the optoelectronic semiconductor chips are oriented toward the back side of the substrate. The optoelectronic semiconductor chips are electrically conductively connected to the grid. A filler material is arranged on the back side of the substrate. The optoelectronic semiconductor chips are embedded in the filler material in such a way that the back sides of the optoelectronic semiconductor chips are not covered by the filler material. A driver chip is arranged over the back sides of the optoelectronic semiconductor chips. The optoelectronic semiconductor chips are electrically conductively connected to the driver chip.

The grid for the electrical contacting of the optoelectronic semiconductor chips, which is provided on the back side of the substrate, may advantageously also ensure optical separation of the pixels, embodied by the optoelectronic semiconductor chips, of the optoelectronic component, which can ensure an increased contrast ratio. The grid is additionally used to receive the wavelength-converting material, so that the optoelectronic component offers integrated wavelength conversion. A further advantage of this optoelectronic component is that the optoelectronic semiconductor chips are electrically contacted both from their front sides and from their back sides, which can simplify the conductor layout and improve thermal coupling of the optoelectronic semiconductor chips.

In one embodiment of the optoelectronic component, it comprises more than 50 000 optoelectronic semiconductor chips, in particular more than 100 000 optoelectronic semiconductor chips. This makes image generation with a high resolution possible for the optoelectronic component.

In one embodiment of the optoelectronic component, at least one of the optoelectronic semiconductor chips is formed as a light-emitting diode chip, as a VCSEL chip or as a detector chip. It is also possible that the optoelectronic component comprises optoelectronic semiconductor chips of different types, which may respectively be formed as light-emitting diode chips, as VCSEL chips or as detector chips. This advantageously allows a high flexibility in the configuration of the optoelectronic component.

In one embodiment of the optoelectronic component, the filler material is a spin-on glass. Advantageously, the filler material may then be applied simply and economically and has favorable mechanical and dielectric properties.

In one embodiment of the optoelectronic component, the filler material is reflective or absorbent. Advantageously, crosstalk between neighboring optoelectronic semiconductor chips may be reduced particularly effectively in this way.

In one embodiment of the optoelectronic component, the driver chip is a silicon chip. Advantageously, the driver chip may then integrate different electronic functionalities.

In one embodiment of the optoelectronic component, the substrate consists of a glass. Advantageously, light generated by the optoelectronic component may then be radiated through the substrate.

In one embodiment of the optoelectronic component, a front side of the substrate comprises structuring. For example, such structuring may offer an optical functionality. For instance, the front side of the substrate may for example be configured as a microlens array.

The above-described properties, features and advantages of this invention, as well as the way in which they are achieved, will become clearer and more easily understandable in conjunction with the following description of the exemplary embodiments that are explained in more detail in connection with the drawings, in which, respectively in a schematized representation,

FIG. 1 shows a substrate with a grid arranged on its back side;

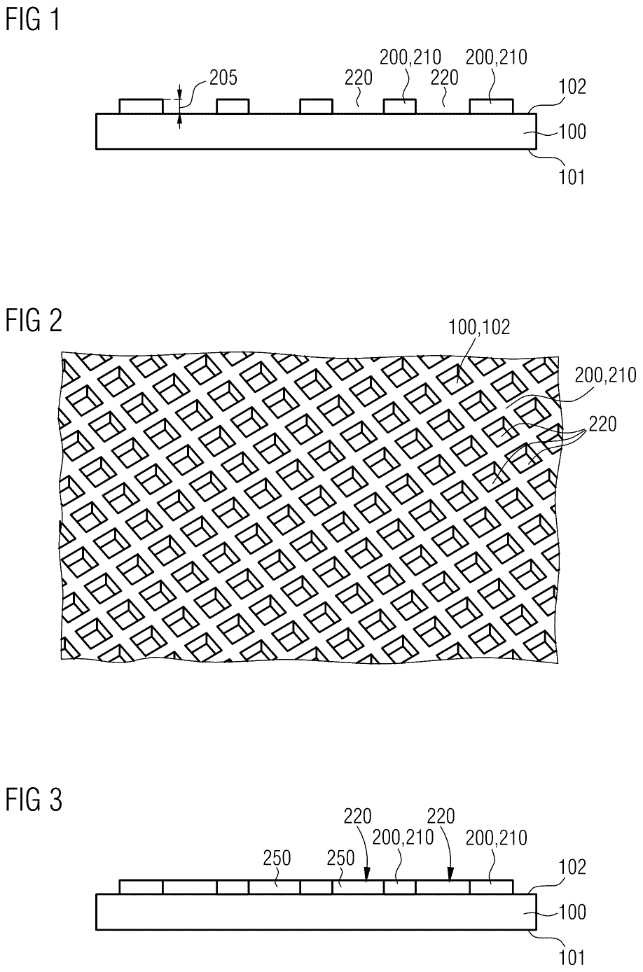

FIG. 2 shows a top view of the grid;

FIG. 3 shows the grid with wavelength-converting material arranged in cells of the grid;

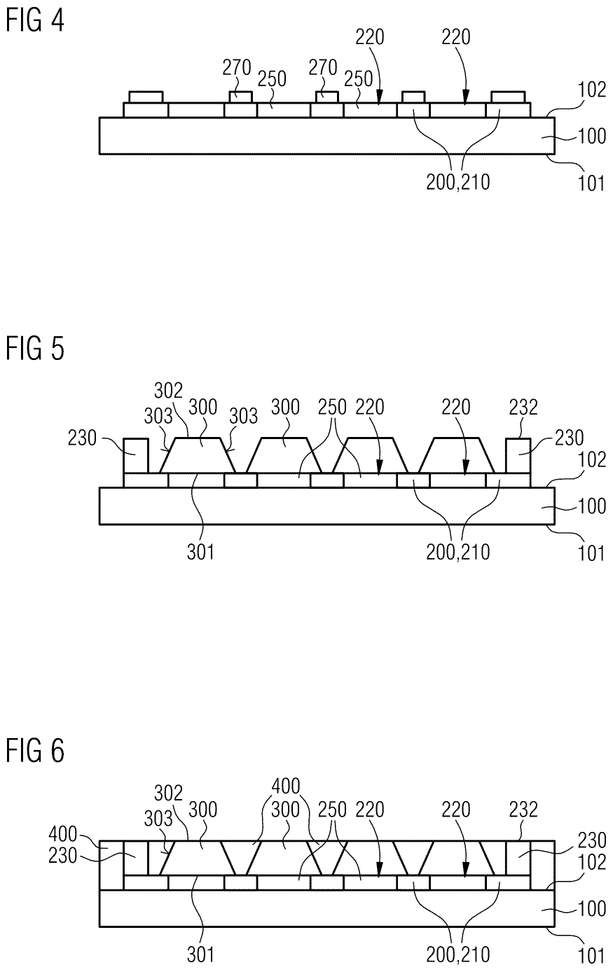

FIG. 4 shows the grid with a connecting material arranged thereon;

FIG. 5 shows optoelectronic semiconductor chips arranged over the cells of the grid;

FIG. 6 shows a filler material, which is arranged on the back side of the substrate and in which the optoelectronic semiconductor chips have been embedded; and

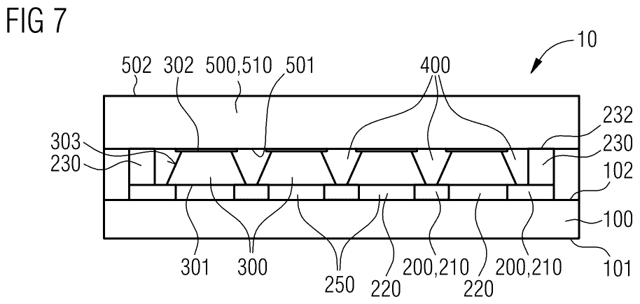

FIG. 7 shows an optoelectronic component obtained by further processing steps.

FIG. 1 shows a schematic sectional side view of a substrate 100 having a front side 101 and a back side 102, which lies opposite the front side 101. The substrate 100 may also be referred to as a carrier. The substrate 100 consists of a transparent material, for example a glass. The substrate 100 may, for example, be formed as a glass wafer.

In a direction measured perpendicularly to the front side 101 and the back side 102, the substrate 100 may for example have a thickness of between 50 μm and 500 μm, in particular for example a thickness of between 50 μm and 150 μm.

A grid 200 having walls 210 consisting of an electrically conductive material has been formed on the back side 102 of the substrate 100. The electrically conductive material may, for example, comprise copper. In a direction perpendicular to the back side 102 of the substrate 100, the walls 210 of the grid 200 have a thickness 205 which, for example, may lie between 2 μm and 20 μm.

FIG. 2 shows a schematic perspective representation of a top view of a part of the grid 200 formed on the back side 102 of the substrate 100. Cells 220 of the grid 200 are formed between the walls 210. In the example represented, the cells 220 have an approximately square shape. The cells 220 may, however, also have a different rectangular shape or a non-rectangular shape. In the example represented in FIGS. 1 and 2, all the walls 210 of the grid 200 are connected continuously to one another and respectively surround the cells 220 fully and in a closed fashion. The grid 200 could, however, also comprise a plurality of portions that are separated from one another, each of which comprises a small number of walls. For example, the grid 200 could be subdivided in rows or columns into portions that are detached from one another, each of which is electrically separated from the others. In this case, it is possible that the walls 210 do not surround the cells 220 of the grid 200 fully and in a closed fashion. Instead, neighboring cells 220 could for example be open to one another.

FIG. 3 shows a schematic sectional side view of the substrate 100 having the grid 200 arranged on its back side 102 in a processing state chronologically following the representation of FIGS. 1 and 2. A wavelength-converting material 250 has been arranged in the cells 220 of the grid 200. It is expedient for the wavelength-converting material 250 to fill the cells 220 fully but to be limited to the cells 220, and for it not to cover the walls 210 lying in between. The introduction of the wavelength-converting material 250 into the cells 220 of the grid 200 may, for example, have taken place by a spray method (spray-coating) or by doctor blading. Masking or a template may optionally have been used.

In the example represented, all the cells 220 of the grid 200 have been filled with the wavelength-converting material 250. It is, however, possible selectively not to fill particular cells 220 of the grid 200 with wavelength-converting material 250. These cells 220 remain free. It is likewise possible to fill different cells 220 with different wavelength-converting material 250.

The wavelength-converting material 250 is formed in order to convert light having a wavelength in a first wavelength range at least partially into light having a wavelength in a different wavelength range. For example, the wavelength-converting material 250 may be formed in order to convert light having a wavelength in the blue or ultraviolet spectral range into light having a wavelength in the yellow or orange spectral range.

FIG. 4 shows a schematic sectional side view of a processing state chronologically following the representation of FIG. 3. An electrically conductive connecting material 270 has been arranged on the walls 210 of the grid 200. The connecting material 270 may for example be a solder, and it may for example consist of indium or an tin-indium alloy. The connecting material 270 may, for example, have been applied by chemical vapor deposition (CVD) or a sputtering method, and it may for example have a layer thickness of between 200 nm and 400 nm. It is expedient for the connecting material 270 to cover the walls 210 substantially fully.

FIG. 5 shows a schematic sectional side view of a processing state chronologically following the representation of FIG. 4.

Optoelectronic semiconductor chips 300 have been arranged over the cells 220 of the grid 200 on the back side 102 of the substrate 100. Each of the optoelectronic semiconductor chips 300 comprises a front side 301 and a back side 302, which lies opposite the front side 301. The optoelectronic semiconductor chips 300 have been arranged so that their front sides 301 are oriented toward the back side 102 of the substrate 100.

The optoelectronic semiconductor chips 300 have been electrically conductively connected on their front sides 301 via the connecting material 270 to the grid 200. If all the portions of the grid 200 are electrically conductively connected to one another, the front sides 301 of all the optoelectronic semiconductor chips 300 are also electrically conductively connected to one another. If the grid 200 comprises a plurality of portions electrically isolated from one another, the front sides 301 of all the optoelectronic semiconductor chips 300 connected to a common portion of the grid 200 are electrically conductively connected to one another.

It is expedient for an optoelectronic semiconductor chip 300 to be arranged over each cell 220 of the grid 200. It is however also possible that individual cells 220 of the grid 200 remain free.

All the optoelectronic semiconductor chips 300 may be of the same type, i.e. formed identically. It is, however, also possible to arrange optoelectronic semiconductor chips 300 of different types over the cells 220 of the grid 200. At least some of the optoelectronic semiconductor chips 300 may for example be formed as light-emitting diode chips (LED chips). At least some of the optoelectronic semiconductor chips 300 may be formed as vertically emitting laser chips (VCSEL chips). Optoelectronic semiconductor chips 300 formed as light-emitting diode chips or as laser chips are intended to radiate light on their front sides 301. If wavelength-converting material 250 is arranged in the cell 220 of the grid 200 that is allocated to such an optoelectronic semiconductor chip 300, the wavelength-converting material 250 may convert the light radiated by the optoelectronic semiconductor chip 300 partially or fully into light with a different wavelength. If no wavelength-converting material 250 is arranged in the allocated cell 220 of the grid 200, the light emitted by the optoelectronic semiconductor chip 300 remains unconverted.

All the optoelectronic semiconductor chips 300 formed as light-emitting diode chips or as laser chips may be configured identically and intended for emission of light in the same wavelength range. It is, however, also possible that the optoelectronic semiconductor chips 300 comprise semiconductor chips intended for emission of light in different wavelength ranges. For example, it is conceivable that optoelectronic semiconductor chips 300 which are intended for emission of light having a blue, red and green light color are respectively arranged over neighboring cells 220 of the grid 200. Each set of such cells 220 and optoelectronic semiconductor chips 300 may then be combined to form a logical pixel.

At least some optoelectronic semiconductor chips 300 may also be formed as detector chips, for example as photodiodes or as phototransistors. In this case, it is expedient not to fill the associated cells 220 of the grid 200 with wavelength-converting material 250.

The front sides 301 of the optoelectronic semiconductor chips 300 each have a size that is matched to the size of the associated cell 220 of the grid 200. It is expedient for the front sides 301 of the optoelectronic semiconductor chips 300 each to be slightly larger than the allocated cells 220 of the grid 200, so that the connecting material 270 arranged on the walls 210 surrounding the respective cell 220 can electrically contact the respective optoelectronic semiconductor chip 300. The front sides 301 of the optoelectronic semiconductor chips 300 may, for example, have edge lengths in the range of between 10 μm and 50 μm. It is conceivable that different optoelectronic semiconductor chips 300 arranged over the cells 220 of the grid 200 have different sizes. In this case, different cells 220 of the grid 200 may also have different sizes.

It is expedient to arrange the optoelectronic semiconductor chips 300 over the cells 220 of the grid 200 by a parallel method. A plurality or all of the optoelectronic semiconductor chips 300 are in this case respectively arranged simultaneously over the cells 220 of the grid 200 on the back side 102 of the substrate 100 in a common working step.

In a further processing step, one or more via structures 230 have been provided on the back side 102 of the substrate 100. The via structures 230 are electrically conductively connected to the grid 200. If the grid 200 comprises a plurality of portions that are electrically separated from one another, at least one via structure 230 will have been provided per portion of the grid 200. It may, however, also be expedient to provide a plurality of via structures 230 for an electrically continuous portion of the grid 200, these being for example distributed over different regions of the grid 200.

In the example represented, the via structures 230 are arranged on the walls 210 of the grid 200 and in this way electrically conductively connected to the walls 210 of the grid 200. Other arrangements are, however, likewise possible.

The via structures 230 extend from the grid 200 away from the substrate 100 in a direction perpendicular to the back side 102 of the substrate 100. Each via structure 230 comprises a back side 232, which faces away from the grid 200 and is expediently arranged in a common plane with the back sides 302 of the optoelectronic semiconductor chips 300.

The via structures 230 may, for example, be applied onto the grid 200 as prefabricated elements and electrically conductively connected to the latter. It is also possible to produce the via structures 230 directly on the back side 102 of the substrate 100, or on the walls 210 of the grid 200, for example by an electroplating method.

FIG. 6 shows a schematic sectional side view of a processing state chronologically following the representation of FIG. 5. A filler material 400 has been arranged on the back side 102 of the substrate 100. The optoelectronic semiconductor chips 300 have been embedded in the filler material 400 in such a way that the back sides 302 of the optoelectronic semiconductor chips 300 are not covered by the filler material 400. Side faces 303 that extend between the front sides 301 and the back sides 302 of the optoelectronic semiconductor chips 300, on the other hand, have been covered by the filler material 400. The via structures 230 have also been embedded in the filler material 400, the back sides 232 of the via structures 230 also not being covered by the filler material 400.

The filler material 400 is a dielectric material. The filler material 400 may, for example, consist of a glass. For example, the filler material 400 may be a spin-on glass. The filler material 400 may be formed so that it is transparent or optionally reflective or absorbent, for example by an admixture of reflective or absorbent particles.

The filler material 400 may have been arranged on the back side 102 of the substrate 100 so that the back sides 302 of the optoelectronic semiconductor chips 300 and the back sides 232 of the via structures 230 will have been initially covered by the filler material 400. In this case, a part of the filler material 400 may subsequently have been removed in order to expose the back sides 302 of the optoelectronic semiconductor chips 300 and the back sides 232 of the via structures 230. This may for example have taken place by planarization, for example by an etching method.

It is possible that the filler material 400 will have also been arranged in cells 220 of the grid 200 in which no wavelength-converting material 250 was previously arranged. If, during the preceding processing steps, a distance has remained between the front sides 301 of the optoelectronic semiconductor chips 300 arranged over the cells 220 and the wavelength-converting material 250 arranged in the cells 220, the filler material 400 may also fill up this space.

FIG. 7 shows a schematic sectional side view of a processing state chronologically following the representation of FIG. 6. A driver chip 500 has been arranged over the back sides 302 of the optoelectronic semiconductor chips 300, over the back sides 232 of the via structures 230 and over the filler material 400. A front side 501 of the driver chip is oriented toward the back sides 302 of the optoelectronic semiconductor chips 300 and toward the back sides 232 of the via structures 230. The back sides 302 of the optoelectronic semiconductor chips 300 and the back sides 232 of the via structures 230 have been electrically conductively connected to contact pads provided on the front side 501 of the driver chip 500.

The driver chip 500 may, for example, be formed as a silicon chip. The driver chip 500 may, however, also be based on another semiconductor system, for example on a III-V semiconductor system. The driver chip 500 comprises electrical circuits for driving the optoelectronic semiconductor chips 300, and it may comprise further electronic functionalities. The driving of the optoelectronic semiconductor chips 300 takes place via the electrically conductive connections between the back sides 302 of the optoelectronic semiconductor chips 300 and the electrical contacts on the front side 501 of the driver chip 500, as well as via the contacts that are provided by the connecting material 270, the grid 200 and the via structures 230 between the front sides 301 of the optoelectronic semiconductor chips 300 and the allocated electrical contact pads on the front side 501 of the driver chip 500.

In the processing state shown in FIG. 7, the arrangement represented forms an optoelectronic component 10, the production of which may have been completed. The front side 101 of the substrate 100 forms a front side of the optoelectronic component 10. A back side 502 of the driver chip 500, which lies opposite the front side 501 of the driver chip 500, forms a back side of the optoelectronic component 10. The optoelectronic component 10 is formed in order to radiate light, which is generated by the optoelectronic semiconductor chips 300, on the front side 101 of the substrate 100. It may be possible to drive the optoelectronic semiconductor chips 300 separately from one another in order to generate a two-dimensional light pattern that is composed of individual pixels and has a predeterminable and variable shape. The optoelectronic component 10 may for example comprise more than 10 000, more than 50 000 or even more than 100 000 optoelectronic semiconductor chips 300, which may for example be arranged in a rectangular matrix arrangement.

The grid 200 on the back side 102 of the substrate 100, which electrically contacts the optoelectronic semiconductor chips 300, advantageously at the same time forms a stop which optically shields the optoelectronic semiconductor chips 300 arranged over neighboring cells 220 of the grid 200 from one another. A high contrast ratio may thereby be achievable between neighboring pixels of the optoelectronic component 10.

The substrate 100 may comprise one or more integrated optical functionalities. For example, the front side 101 of the substrate 100 may comprise structuring that has a light-shaping effect. For example, the front side 101 of the substrate 100 may be configured as a microlens array, one microlens being for example arranged over each cell 220 of the grid 200. It is expedient to apply the structuring of the front side 101 of the substrate 100 already before the processing step, which is shown in FIG. 1, of forming the grid 200 on the back side 102 of the substrate 100 is carried out.

The production method described above may be carried out at the wafer level, in such a way that a plurality of identical optoelectronic components 10 are produced simultaneously in common processing steps. For this purpose, the substrate 100 is provided in a sufficient size, for example as a glass wafer. A plurality of identical grids 200 are formed next to one another on the back side 102 of the substrate 100, for example in a matrix arrangement. The processing steps described above then take place simultaneously and in the same way for each of the grids 200. The filler material 400 is arranged over the back side 102 of the entire substrate 100 so that the optoelectronic semiconductor chips 300 of all the optoelectronic components 10 obtainable by the method are embedded simultaneously in the filler material 400. The driver chip 500 is provided together with further identical driver chips 500 in a wafer assembly 510, and is connected to the arrangement so that the optoelectronic semiconductor chips 300 allocated to a grid 200 are each electrically conductively connected to one of the driver chips 500. To complete the processing, a step of singulating the optoelectronic components 10 takes place, the substrate 100 and the wafer assembly 510 being divided in such a way that each optoelectronic component 10 respectively comprises a portion of the substrate 100 that has one of the grids 200 and one of the driver chips 500.

The invention has been illustrated and described in detail with the aid of the preferred exemplary embodiments. Nevertheless, the invention is not restricted to the examples disclosed. Other variants may be derived by a person skilled in the art.

### LIST OF REFERENCE SIGNS

| | |
|---|---|
| 10 | optoelectronic component |
| 100 | substrate |
| 101 | front side |
| 102 | back side |
| 200 | grid |
| 205 | thickness |
| 210 | wall |
| 220 | cell |
| 230 | via structure |
| 232 | back side |
| 250 | wavelength-converting material |
| 270 | connecting material |
| 300 | optoelectronic semiconductor chip |
| 301 | front side |
| 302 | back side |
| 303 | side face |
| 400 | filler material |
| 500 | driver chip |
| 501 | front side |
| 502 | back side |
| 510 | wafer assembly |

1. A method for producing an optoelectronic component, comprising the following steps:
forming a grid having walls consisting of an electrically conductive material on a back side of a transparent substrate, cells of the grid being formed between the walls;
arranging a wavelength-converting material in at least one cell of the grid;
arranging optoelectronic semiconductor chips over the cells of the grid, each optoelectronic semiconductor chip comprising a front side and a back side,
the front sides of the optoelectronic semiconductor chips being oriented toward the back side of the substrate,
the optoelectronic semiconductor chips being electrically conductively connected to the grid;
arranging a filler material on the back side of the substrate,
the optoelectronic semiconductor chips being embedded in the filler material in such a way that the back sides of the optoelectronic semiconductor chips are not covered by the filler material;
arranging a driver chip over the back sides of the optoelectronic semiconductor chips,
the optoelectronic semiconductor chips being electrically conductively connected to the driver chip.

2. The method according to claim 1,
wherein the following step is carried out before the arranging of the filler material:
providing a via structure, which is electrically conductively connected to the grid, on the back side of the substrate,
the via structure being embedded in the filler material in such a way that a back side of the via structure is not covered by the filler material,
the via structure being electrically conductively connected to the driver chip.

3. The method according to claim 1, wherein no wavelength-converting material is arranged in at least one cell of the grid.

4. The method according to claim 3,
wherein the filler material is also arranged in cells in which no wavelength-converting material is arranged.

5. The method according to claim 1, wherein optoelectronic semiconductor chips of different types are arranged over the cells of the grid.

6. The method according to claim 1, wherein the following step is carried out after the arranging of the filler material on the back side of the substrate:
removing a part of the filler material in order to expose the back sides of the optoelectronic semiconductor chips.

7. The method according to claim 1, wherein the following step is carried out before the arranging of the optoelectronic semiconductor chips:
arranging an electrically conductive connecting material on the walls of the grid;
the optoelectronic semiconductor chips being electrically conductively connected to the grid via the connecting material.

8. The method according to claim 1, wherein the grid is formed with a thickness of between 2 μm and 20 μm.

9. The method according to claim 1, wherein, in addition to the grid, identical further grids are formed on the back side of the substrate,
wherein the processing steps above are also carried out for each further grid,
wherein the driver chip is provided together with identical further driver chips in a wafer assembly,
wherein the optoelectronic semiconductor chips allocated to one of the further grids are electrically conductively connected to one of the further driver chips,
wherein the method comprises the following further step:
singulating the optoelectronic component and further identical optoelectronic components.

10. An optoelectronic component
comprising a transparent substrate having a back side,
wherein a grid having walls consisting of an electrically conductive material is formed on the back side of the substrate, cells of the grid being formed between the walls,
wherein a wavelength-converting material is arranged in at least one cell of the grid,
wherein optoelectronic semiconductor chips are arranged over the cells of the grid,
wherein each optoelectronic semiconductor chip comprises a front side and a back side,
wherein the front sides of the optoelectronic semiconductor chips are oriented toward the back side of the substrate,
wherein the optoelectronic semiconductor chips are electrically conductively connected to the grid,
wherein a filler material is arranged on the back side of the substrate, wherein the optoelectronic semiconductor chips are embedded in the filler material in such a way that the back sides of the optoelectronic semiconductor chips are not covered by the filler material,
wherein side faces of the optoelectronic semiconductor chips that extend between the front sides and the back sides of the optoelectronic semiconductor chips are covered by the filler material,
wherein a driver chip is arranged over the back sides of the optoelectronic semiconductor chips,
wherein the optoelectronic semiconductor chips are electrically conductively connected to the driver chip.

11. The optoelectronic component according to claim 10, wherein the optoelectronic component comprises more than 10000 optoelectronic semiconductor chips, in particular more than 50000 optoelectronic semiconductor chips, in particular more than 100 000100000 optoelectronic semiconductor chips.

12. The optoelectronic component according to claim 10,
wherein at least one of the optoelectronic semiconductor chips is formed as a light-emitting diode chip, as a VCSEL chip or as a detector chip.

13. The optoelectronic component according to claim 10,
wherein the filler material is a spin-on glass.

14. The optoelectronic component according to claim 10,
wherein the filler material is reflective or absorbent.

15. The optoelectronic component according to claim 10,
wherein the driver chip is a silicon chip.

16. The optoelectronic component according to claim 10,
wherein the substrate consists of a glass.

17. The optoelectronic component according to claim 10,
wherein a front side of the substrate comprises structuring.
